(19) United States
(12) Patent Application Publication
(10) Pub. No.: US 2016/0252752 A1
(43) Pub. Date: Sep. 1, 2016

(54) DISPLAY PANEL ASSEMBLY AND METHODS OF MAKING SAME

(71) Applicant: 3M INNOVATIVE PROPERTIES COMPANY, St. Paul, MN (US)

(72) Inventors: Stanley C. Busman, North St. Paul, MN (US); David Scott Thompson, West Lakeland, MN (US); Robert S. Davidson, Bloomington, MN (US); Audrey A. Sherman, Woodbury, MN (US); Pei Tien, Taoyuan (TW)

(73) Assignee: 3M INNOVATIVE PROPERTIES COMPANY

(21) Appl. No.: 15/149,700

(22) Filed: May 9, 2016

Related U.S. Application Data
(62) Division of application No. 13/516,413, filed on Oct. 23, 2012.
(60) Provisional application No. 61/287,239, filed on Dec. 17, 2009.
(60) Provisional application No. 61/384,927, filed on Sep. 21, 2010.

(51) Int. Cl. G02F 1/01; H01L 51/52; H05B 33/04; H01L 51/00

(52) U.S. Cl. CPC G02F 1/0107; H01L 51/0043; H01L 51/5246; H05B 33/04

(57) ABSTRACT

A display panel assembly is made by optically bonding a display panel and a substantially transparent substrate. Optical bonding is carried out by forming an optical bonding layer having regions of different physical properties.

### FIELD

This disclosure relates to components used in display devices, and particularly to assemblies having a display panel optically bonded to an optical substrate.

### BACKGROUND

Optical bonding may be used to adhere together two optical elements using an optical grade optical bonding composition. In display applications, optical bonding may be used to adhere together optical elements such as display panels, glass plates, touch panels, diffusers, rigid compensators, heaters, and flexible films such as polarizers and retarders. The optical performance of a display can be improved by minimizing the number of internal reflecting surfaces, thus it may be desirable to remove or at least minimize the number of air gaps between optical elements in the display.

### SUMMARY

A display panel assembly is disclosed herein. In some embodiments, the display panel assembly comprises: a display panel; a substantially transparent substrate; and an optical bonding layer disposed between the display panel and the substantially transparent optical substrate, the optical bonding layer comprising a first region and a second region substantially surrounding the first region, wherein the second region has a hardness greater than that of the first.

In some embodiments, the display panel assembly comprises: a display panel; a substantially transparent substrate; and a curable layer disposed between the display panel and the substantially transparent optical substrate, the curable layer comprising a first composition and a second composition substantially surrounding the first composition, wherein the viscosity of the second composition is less than that of the first.

Methods of optical bonding are disclosed herein. In some embodiments, the method comprises: providing a display panel and a substantially transparent optical substrate; providing a first composition comprising a first ethylenically unsaturated compound having at least one ethylenically unsaturated group; providing a second composition comprising a second ethylenically unsaturated compound having at least two ethylenically unsaturated groups, wherein the first and/or second compositions comprise a catalyst; dispensing the first and second compositions on a first major surface of the display panel such that the second composition substantially surrounds the first; contacting a second major surface of the substantially transparent optical substrate with the first and/or second compositions dispensed on the first major surface of the display panel such that a curable layer comprising the first and second compositions is formed between the first and second major surfaces; and curing the curable layer to form an optical bonding layer comprising a first region and a second region substantially surrounding the first region, wherein the second region has a hardness greater than that of the first.

In some embodiments, the method comprises: providing a display panel and a substantially transparent optical substrate; providing a first composition comprising a first ethylenically unsaturated compound having at least one ethylenically unsaturated group; providing a second composition comprising a second ethylenically unsaturated compound having at least two ethylenically unsaturated groups, wherein the first and/or second compositions comprise a catalyst; dispensing the first composition on a first major surface of the display panel; contacting a second major surface of the substantially transparent optical substrate with the first composition dispensed on the first major surface of the display panel such that a first curable layer comprising the first composition is formed between the first and second major surfaces; curing the first curable layer to form a first cured layer; dispensing the second composition on at least one exposed edge of the first cured layer; and curing the second composition dispensed on the at least one exposed edge of the first cured layer thereby forming an optical bonding layer, the optical bonding layer comprising a first region and a second region substantially surrounding the first region, wherein the second region has a hardness greater than that of the first.

In some embodiments, the method comprises: providing a display panel and a substantially transparent optical substrate; providing a first composition comprising a first ethylenically unsaturated compound having at least one ethylenically unsaturated group; providing a second composition comprising a second ethylenically unsaturated compound having at least two ethylenically unsaturated groups, wherein the first and/or second compositions comprise a catalyst; dispensing the first composition on a first major surface of the display panel; contacting a second major surface of the substantially transparent optical substrate with the first composition dispensed on the first major surface of the display panel such that a first curable layer comprising the first composition is formed between the first and second major surfaces; dispensing the second composition on at least one exposed edge of the first curable layer; and curing the first and second compositions thereby forming an optical bonding layer, the optical bonding layer comprising a first region and a second region substantially surrounding the first region, wherein the second region has a hardness greater than that of the first.

In some embodiments, the method comprises: providing a display panel and a substantially transparent optical substrate; providing a first composition comprising a first ethylenically unsaturated compound having at least one ethylenically unsaturated group; providing a second composition comprising a second ethylenically unsaturated compound having at least two ethylenically unsaturated groups, wherein the first and/or second compositions comprise a catalyst; dispensing the first composition on a first major surface of the display panel; dispensing the second composition on a second major surface of the substantially transparent substrate; contacting the first composition dispensed on the first major surface with the second composition dispensed on the second major surface, such that a curable layer comprising the first and second compositions is formed between the first and second major surfaces; and curing the curable layer thereby forming an optical bonding layer comprising a first region and a second region substantially surrounding the first region, wherein the second region has a hardness greater than that of the first.

In some embodiments, the method comprises: providing a display panel and a substantially transparent optical substrate; providing a first composition comprising a first ethylenically unsaturated compound having at least one ethylenically unsaturated group; providing a second composition comprising a second ethylenically unsaturated compound, wherein the first and/or second compositions comprise a catalyst; dispensing the first composition on a first major surface of the display panel; dispensing the second composition on the first composition after the first composition is dispensed on the first major surface; and contacting a second major surface of the substantially transparent optical substrate with the first and/or second compositions dispensed on the first major surface, such that a curable layer comprising the first and second compositions is formed between the first and second major surfaces.

### BRIEF DESCRIPTION OF THE DRAWINGS

Advantages and features of the invention may be more completely understood by consideration of the following figures in connection with the detailed description provided below. The figures are schematic drawings and illustrations and are not necessarily drawn to scale.

FIG. 1 is a schematic cross-sectional view of an exemplary display panel assembly.

FIGS. 2A and 2B are schematic top-down views of embodiments in which first and second compositions are disposed on a first major surface of a first optical substrate.

FIG. 3A is a schematic top-down view of an embodiment in which a second composition is disposed on a first composition that has been disposed on a first major surface of a first optical substrate.

FIG. 3B is a schematic cross-sectional view of an exemplary display panel assembly that may be made using the embodiment described in FIG. 3A.

FIG. 3C is a schematic top-down view of the exemplary display panel assembly shown in FIG. 3B.

FIGS. 4A and 4B are schematic cross-sectional views showing another embodiment by which a display panel assembly disclosed herein may be made.

FIG. 4C is a schematic top-down view of an exemplary display panel assembly that may be made using the embodiments shown in FIGS. 2A, 2B, 4A and 4B.

FIG. 5A is a schematic top-down view of an embodiment in which a first composition is disposed on a first major surface of a first optical substrate.

FIG. 5B is a schematic top-down view of an embodiment in which a second composition is disposed on a second major surface of a second optical substrate.

FIG. 5C is a schematic cross-sectional view of an exemplary method by which an exemplary display panel assembly may be made using the embodiments shown in FIGS. 5A and 5B.

FIG. 5D is a schematic cross-sectional view of an exemplary display panel assembly formed from the embodiment shown in FIG. 5C.

FIGS. 5E and 5F are schematic top-down views of exemplary optical assemblies formed from the embodiment shown in FIG. 5C.

FIGS. 6A and 6B are schematic cross-sectional views showing how an exemplary display panel assembly may be made.

### DETAILED DESCRIPTION

This application is related to U.S. Provisional Application Ser. No. 61/164,234 (Busman et al., filed Mar. 27, 2009); International Application Number PCT/US10/028382 (Busman et al., filed Mar. 24, 2010); International Application Number PCT/US10/047016 (Busman et al., filed Aug. 27, 2010); U.S. Provisional Application Ser. No. 61/287,239 (Busman et al., filed Dec. 17, 2009); the disclosures of which are incorporated by reference herein for all that they contain.

Optical materials may be used to fill gaps between optical components or substrates of optical assemblies. Optical assemblies comprising a display panel bonded to an optical substrate may benefit if the gap between the two is filled with an optical material that matches or nearly matches the refractive indices of the panel and the substrate. For example, sunlight and ambient light reflection inherent between a display panel and an outer cover sheet may be reduced. Color gamut and contrast of the display panel can be improved under ambient conditions. Optical assemblies having a filled gap can also exhibit improved shock-resistance compared to the same assemblies having an air gap.

Many optical materials are not suitable for use in high performance applications such as high definition televisions. Many optical materials are susceptible to yellowing over time. Known optical materials may have low stress absorption causing bond failure during impact or thermal stress.

A display panel assembly having a large size or area can be difficult to manufacture, especially if efficiency and stringent optical quality are desired. A gap between optical components may be filled by pouring or injecting a curable composition into the gap followed by curing the composition to bond the components together. However, these commonly used compositions have long flow-out times which contribute to inefficient manufacturing methods for large optical assemblies. Some optical materials used to form optical bonding layers are difficult to work with during assembly resulting in defects when the optical bonding layer is formed. If there are any errors introduced during the fabrication of bonded displays, it can be difficult to rework any of the parts, resulting in yield loss and increased cost.

Optical materials used to fill gaps between optical components or substrates typically comprise adhesives and various types of cured polymeric compositions. However, these optical materials are not useful for making a display panel assembly if, at a later time, one wishes to disassemble or rework the assembly with little or no damage to the components. This reworkability feature is needed for optical assemblies because the components tend to be fragile and expensive. For example, a cover sheet often needs to be removed from a display panel if flaws are observed during or after assembly or if the cover sheet is damaged after sale. It is desirable to rework the assembly by removing the cover sheet from the display panel with little or no damage to the components. Reworkability of optical assemblies is becoming increasingly important in the display industry as larger and larger display panels are becoming available.

The optical assembly disclosed herein comprises two optical components or substrates, particularly a display panel and a substantially light transmissive substrate, bonded together with a novel type of optical bonding layer having regions of different properties. For example, the optical bonding layer may be soft and gel-like throughout most of the gap between the substrates, yet may be relatively harder and less tacky at or near the perimeter of one or both substrates. An optical bonding layer having these properties can provide superior adhesion and stress absorption because of the soft and gel-like material, yet be easily handled, exhibit little material transfer and little collection of dust because of the harder material at or near the perimeter of the assembly.

### Methods of Optical Bonding

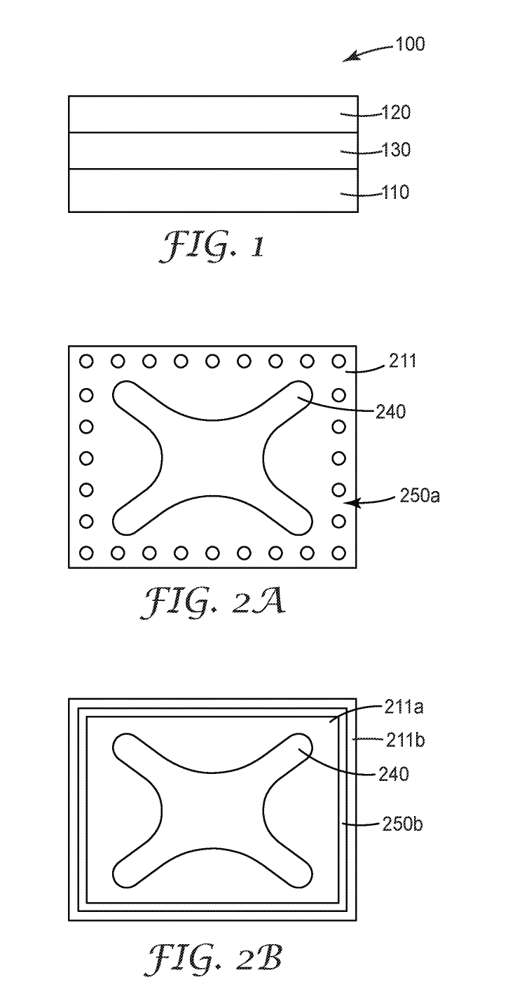

Referring to FIG. 1, there is shown a schematic cross sectional view of exemplary display panel assembly 100 comprising first optical substrate 110, second optical substrate 120, and optical bonding disposed between the substrates. The first and second optical substrates are bonded together by optical bonding layer 130 such that, when display panel assembly 100 is moved, the substrates do not move substantially in relation to one another.

FIG. 2A is a schematic top-down view of an embodiment in which first and second compositions, 240 and 250a respectively, are disposed on first major surface 211 of a first optical substrate. In this embodiment, the display panel assembly disclosed herein is prepared by dispensing first composition 240 onto first major surface 211 in an X-like shape as shown. Second composition 250a is dispensed as dots along the perimeter of first major surface 211.

FIG. 2B is a schematic top-down view of an embodiment in which first and second compositions, 240 and 250b respectively, are disposed on first major surface 211 of a first optical substrate. The dots of second composition 250a are spread evenly with a brush or similarly effective tool to create band 250b which substantially surrounds first composition 240 as shown in FIG. 2B. Alternatively, the band of 250b may be formed directly by applying a line of the second composition using an appropriate application method, for example dispensing from a syringe. For the embodiment shown in FIG. 2B, first major surface 211 comprises two regions 211a and 211b.

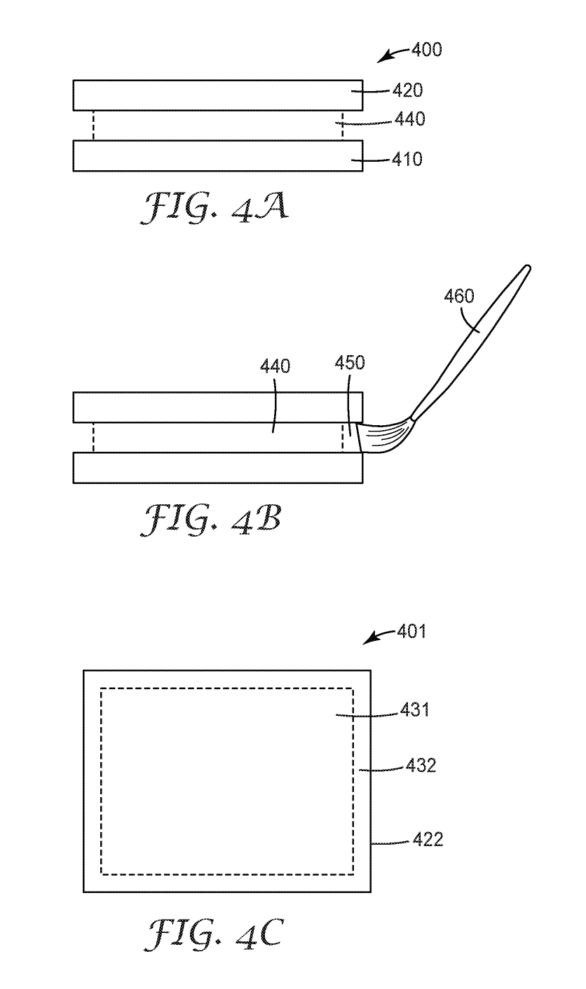

The second optical substrate is slowly lowered down such that a second major surface of the second optical substrate contacts the first composition 240 and/or second compositions 250a and/or 250b such that a curable layer comprising the first and second compositions is formed between the first and second major surfaces. The first and/or second compositions spread out and mix together after contact with the second major surface as the first and second substrates are brought together. The curable layer of the resulting assembly (representative top down schematic shown in FIG. 4C) may then be cured using appropriate means, conditions, and processes as described below. An exemplary optical bonding layer prepared according to this method may have a gel-like, pressure sensitive adhesive-like or adhesive-like central region and a non-tacky perimeter region.

In general, “curable” is sometimes used to describe a composition, layer, region, etc. that cures under predetermined conditions such as application of heat, some type of radiation or energy, or by simply combining two reactive components at room temperature. As used herein, “curable” is used to describe (1) a composition, layer or region that is substantially uncured and becomes only partially cured or substantially completely cured; or (2) a composition, layer or region that is partially cured and partially uncured, and at least some amount of the uncured portion becomes cured; or (3) a composition, layer or region that is substantially uncured and becomes at least partially cured or substantially completely cured.

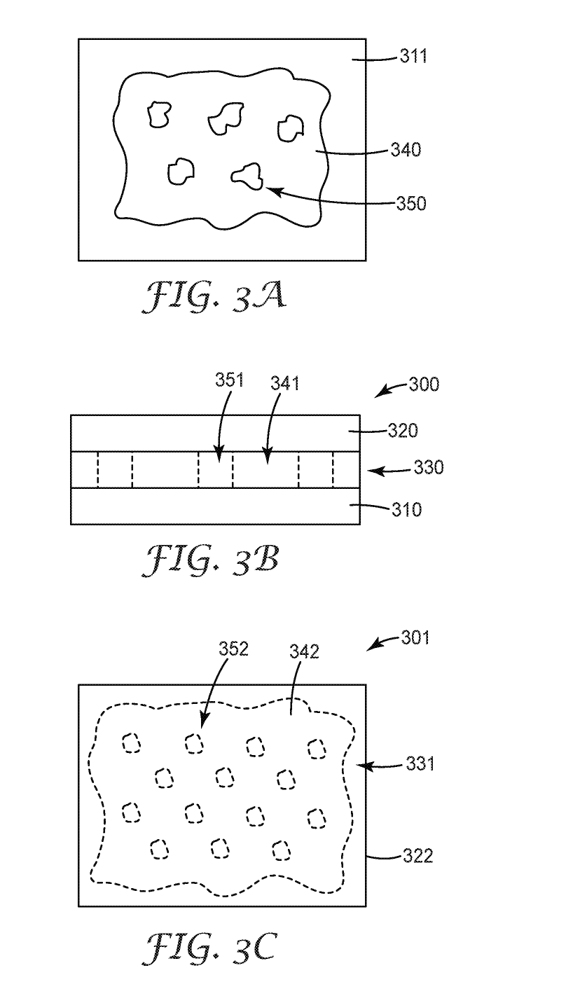

FIG. 3A is a schematic top-down view of another embodiment in which first and second compositions, 340 and 350 respectively, are disposed on first major surface 311 of a first optical substrate. In this embodiment, the display panel assembly disclosed herein is prepared by dispensing first composition 340 onto first major surface 311 such that a large portion, such as a major portion, of the surface is covered. Second composition 350 is dispensed on first composition 340 as dots or spots. The second optical substrate is slowly lowered down such that a major surface of the substrate (the second major surface) contacts the first and/or second compositions dispensed on the first major surface, such that a curable layer comprising the first and second compositions is formed between the first and second major surfaces. The first and/or second compositions generally spread out upon contact with the second major surface, and the compositions mix to some extent depending on compatibility, viscosities, etc. of the compositions. The resulting assembly may then be cured using appropriate means, conditions, etc. as described below.

For FIGS. 3B, 3C, 4B, 4C, 5D-5F, optical bonding layers with dotted lines are shown. The dotted lines are intended to distinguish between different “regions” of the optical bonding layer. In some embodiments, the different regions form with little to no mixing of the first and second compositions. In some embodiments, the different regions form with considerable mixing of the first and second compositions, such that one or more additional regions are formed between the first and second regions. Regardless, the dotted lines are used to distinguish between regions having different properties. The dotted lines are not intended to limit the shape, size, length, etc. of any of the regions having different physical properties. In some embodiments, there may be one or more significant regions between the first and second regions, the one or more significant regions having a gradient of properties between that of the first and second regions. In some embodiments, the second composition by itself is not curable and only becomes curable when mixed with the first composition, such that the mixture of the first and second compositions forms a third composition, which upon curing, becomes one or more second regions of the optical bonding layer.

FIGS. 3B and 3C are schematic views of optical assemblies that may be made from the embodiment shown in FIG. 3A. In FIG. 3B, a schematic cross-sectional view of exemplary optical bonding layer 330, disposed between first major surface 311 of first optical substrate 310 and second major surface 321 of second optical substrate 320, is shown as having regions 341 and 351. In FIG. 3C, a schematic top-down view of exemplary display panel assembly 301 having optical bonding layer 331 disposed between first and second optical substrates; the view is a top-down view showing optical bonding layer 331 through a transparent second optical substrate having perimeter 322. Optical bonding layer 331 has region 342 and regions 352.

Another display panel assembly that may be made from the embodiment shown in FIG. 3A includes those in which the optical bonding layer formed between the first and second optical substrates extends to the perimeter of at least one of the substrates. In this case, the gap between the substrates is substantially filled with the first and second compositions. Yet another display panel assembly that may be made from the embodiment shown in FIG. 3A includes those in which the first and second compositions fill and subsequently overflow from the gap between the first and second optical substrates.

For the embodiment shown in FIG. 3A, a first composition that when cured becomes a tacky gel or tacky material such as a pressure sensitive adhesive, may be used in combination with a quick-curing second composition to anchor rapidly or spot tack two rigid optical substrates to one another. The purpose of the quick-curing second composition is to bond or join rapidly the two substrates together such that the display panel assembly may be handled and moved before the first composition is fully cured. Being able to at least quickly cure a portion of the optical bonding layer such that the display panel assembly may be moved can be very important for manufacturing productivity.

FIGS. 4A and 4B are schematic cross-sectional views showing another embodiment by which a display panel assembly disclosed herein may be made. Referring to FIG. 4A, assembly 400 is prepared by dispensing a first composition on first major surface 411 of first optical substrate 410, then curable layer 440 comprising the first composition is formed by contacting second major surface 421 of second optical substrate 420 with the composition. Subsequently, curable layer 440 may remain uncured or be only partially cured or substantially completely cured. As shown in FIG. 4B, second composition 450 is then dispensed using brush 460 or similar tool onto one or more edges of the assembly such that the second composition is disposed between the substrates. Curing may then be carried out to cure the first and/or second compositions thereby forming the optical bonding layer.

Regarding the embodiment shown in FIG. 4B, the second composition, before or after it is partially cured but still liquid, may contact the first composition which is uncured or only partially cured or substantially completely cured. Alternatively, the second composition, before or after it is cured, may not contact the first composition which is uncured or only partially cured or substantially completely cured. The first and second compositions may mix to some extent depending on, for example, the extent to which each is cured, the compatibility of the compositions, and the viscosities of the compositions.

FIG. 4C is a schematic top-down view of exemplary display panel assembly 401 that may be made as described for FIGS. 2A and 2B and FIGS. 4A and 4B. Display panel assembly 401 has an optical bonding layer (not identified by number) disposed between first and second optical substrates, 410 and 420, respectively. This top-down view shows the optical bonding layer through second optical substrate 420 which is transparent and has perimeter 422. The optical bonding layer has region 431 and region 432. In this embodiment, the optical bonding layer substantially fills the gap to the edges of the substrates, compared to the optical bonding layer shown in FIG. 3C which does not extend to the edges. In some embodiments, the first composition 440 shown in FIG. 4B extends to the edges of the first and second optical substrates and overflows slightly beyond the edges of the optical substrates. Two regions can be formed by the right choice of the second composition such that when brushed on the second composition infiltrates and mixes into the first composition and creates a second region in the optical bonding layer.

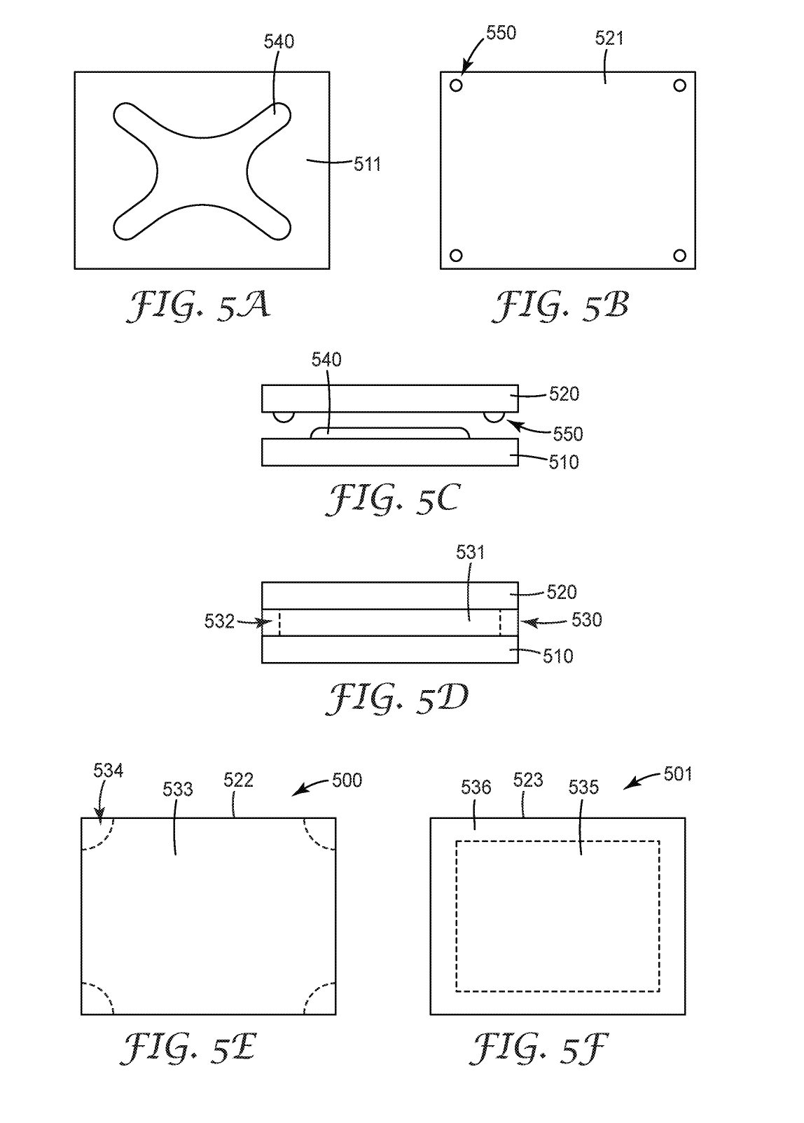

FIGS. 5A-5D show schematic views of additional embodiments of the invention. FIG. 5A is a schematic top-down view in which first composition 540 is dispensed on first major surface 511 of first optical substrate 510, and FIG. 5B is a schematic top-down view in which second composition 550 is dispensed on second major surface 521 of second optical substrate 520 (arrow 550 in FIG. 5B refers to the four dots in the corners on second major surface 521). As shown in FIG. 5C, the two optical substrates with compositions are brought in proximity to one another, and subsequently, when the substrates are close enough, a curable layer comprising the first and second compositions is formed between first major surface 511 and the second major surface 521. FIG. 5D is a schematic cross-sectional view of exemplary display panel assembly 500 comprising optical bonding layer 530, prepared by at least partially curing the curable layer disposed between first major surface 511 and the second major surface 521. Optical bonding layer 530 has region 531 and regions 532.

FIG. 5E is a schematic top-down view of exemplary display panel assembly 501 that may be formed from the embodiment described for FIGS. 5A-C. Display panel assembly 501 has an optical bonding layer (not identified by number) disposed between first and second optical substrates, 510 and 520, respectively. This top-down view shows the optical bonding layer through second optical substrate 520 which is transparent and has perimeter 522. The optical bonding layer has region 533 and regions 534. The optical bonding layer substantially fills the gap between the first and second substrates, i.e., substantially to the edges. In some embodiments, the optical bonding layer may extend slightly beyond the edges of the two optical substrates.

FIG. 5F shows an exemplary display panel assembly that may be formed from an embodiment similar to that shown for FIGS. 5A-C. Display panel assembly 502 has an optical bonding layer (not identified by number) disposed between first and second optical substrates, 510 and 520, respectively. This top-down view shows the optical bonding layer through second optical substrate 520 which is transparent and has perimeter 522. The optical bonding layer has regions 535 and 536, wherein region 536 substantially surrounds region 535. This type of optical bonding layer with regions 535 and 536 can be formed by forming a band of the second composition on the second major surface of the second substrate instead of the four dots in the corners as shown in FIG. 5B. The optical bonding layer substantially fills the gap between, i.e., to the edges, of the first and second substrates. In some embodiments, the optical bonding layer may extend slightly beyond the edges of the two optical substrates.

In general, the display panel assembly is made by bringing the second optical substrate in proximity to the first, and the “angle of approach” between the two substrates may be varied so that optimal formation of the optical bonding layer can occur. As shown in FIG. 5C, the two substrates may be brought in proximity to one another such that they are substantially parallel. This may be the case if first and/or second compositions are present on first and second optical substrates, respectively, as shown in FIG. 5C. Variations of the “parallel approach” may be employed, e.g., either or both of the first and second compositions may present on either or both substrates.

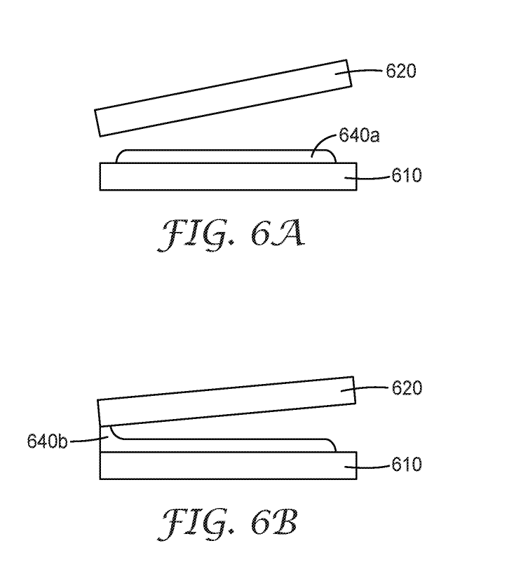

FIG. 6A shows a schematic cross-sectional view in which second optical substrate 620 is brought in proximity to first optical substrate 610 having first composition 640a disposed on first major surface 611. FIG. 6B shows a schematic cross-sectional view after second major surface 621 of second optical substrate 620 contacts first composition 640a which then wets the substrate as shown by 640b. As second optical substrate 620 becomes increasingly parallel to first optical substrate 610, first composition 640b continues to wet out second major surface 621 such that a layer of the first composition is formed between the two substrates. Variations of the “angled approach” may be employed, e.g., either or both of the first and second compositions may present on either or both substrates.

The following methods are variations of the methods described above for FIGS. 1-6B. In some embodiments, the method comprises a method of optical bonding, comprising: providing a display panel and a substantially transparent optical substrate; providing a first composition comprising a first ethylenically unsaturated compound having at least one ethylenically unsaturated group; providing a second composition comprising a second ethylenically unsaturated compound having at least two ethylenically unsaturated groups, wherein the first and/or second compositions comprise a catalyst; dispensing the first and second compositions on a first major surface of the display panel such that the second composition substantially surrounds the first; contacting a second major surface of the substantially transparent optical substrate with the first and/or second compositions dispensed on the first major surface of the display panel such that a curable layer comprising the first and second compositions is formed between the first and second major surfaces; and curing the curable layer to form an optical bonding layer comprising a first region and a second region substantially surrounding the first region, wherein the second region has a hardness greater than that of the first.

In some embodiments, the method comprises a method of optical bonding, comprising: providing a display panel and a substantially transparent optical substrate; providing a first composition comprising a first ethylenically unsaturated compound having at least one ethylenically unsaturated group; providing a second composition comprising a second ethylenically unsaturated compound having at least two ethylenically unsaturated groups, wherein the first and/or second compositions comprise a catalyst; dispensing the first composition on a first major surface of the display panel; contacting a second major surface of the substantially transparent optical substrate with the first composition dispensed on the first major surface of the display panel such that a first curable layer comprising the first composition is formed between the first and second major surfaces; curing the first curable layer to form a first cured layer; dispensing the second composition on at least one exposed edge of the first cured layer; and curing the second composition dispensed on the at least one exposed edge of the first cured layer thereby forming an optical bonding layer, the optical bonding layer comprising a first region and a second region substantially surrounding the first region, wherein the second region has a hardness greater than that of the first.

In some embodiments, the method comprises a method of optical bonding, comprising: providing a display panel and a substantially transparent optical substrate; providing a first composition comprising a first ethylenically unsaturated compound having at least one ethylenically unsaturated group; providing a second composition comprising a second ethylenically unsaturated compound having at least two ethylenically unsaturated groups, wherein the first and/or second compositions comprise a catalyst; dispensing the first composition on a first major surface of the display panel; contacting a second major surface of the substantially transparent optical substrate with the first composition dispensed on the first major surface of the display panel such that a first curable layer comprising the first composition is formed between the first and second major surfaces; dispensing the second composition on at least one exposed edge of the first curable layer; and curing the first and second compositions thereby forming an optical bonding layer, the optical bonding layer comprising a first region and a second region substantially surrounding the first region, wherein the second region has a hardness greater than that of the first.

In some embodiments, the method comprises a method of optical bonding, comprising: providing a display panel and a substantially transparent optical substrate; providing a first composition comprising a first ethylenically unsaturated compound having at least one ethylenically unsaturated group; providing a second composition comprising a second ethylenically unsaturated compound having at least two ethylenically unsaturated groups, wherein the first and/or second compositions comprise a catalyst; dispensing the first composition on a first major surface of the display panel; dispensing the second composition on a second major surface of the substantially transparent substrate; contacting the first composition dispensed on the first major surface with the second composition dispensed on the second major surface, such that a curable layer comprising the first and second compositions is formed between the first and second major surfaces; and curing the curable layer thereby forming an optical bonding layer comprising a first region and a second region substantially surrounding the first region, wherein the second region has a hardness greater than that of the first.

In some embodiments, the method comprises a method of optical bonding, comprising: providing first and second optical substrates; providing a first composition comprising a first ethylenically unsaturated compound having at least one ethylenically unsaturated group; providing a second composition comprising a second ethylenically unsaturated compound having at least two ethylenically unsaturated groups, wherein the first and/or second compositions comprise a catalyst; dispensing the first composition on a first major surface of the first optical substrate; dispensing the second composition on the first major surface; contacting a second major surface of the second optical substrate with the first and/or second compositions dispensed on the first major surface, such that a curable layer comprising the first and second compositions is formed between the first and second major surfaces; and curing the curable layer thereby forming an optical bonding layer comprising a first region and a second region substantially surrounding the first region, wherein the second region has a hardness greater than that of the first.

In some embodiments, the method comprises a method of optical bonding, comprising: providing first and second optical substrates; providing a first composition comprising a first ethylenically unsaturated compound having at least one ethylenically unsaturated group; providing a second composition comprising a second ethylenically unsaturated compound, wherein the first and/or second compositions comprise a catalyst; dispensing the first composition on a first major surface of the first optical substrate; dispensing the second composition on the first composition after the first composition is dispensed on the first major surface; and contacting a second major surface of the second optical substrate with the first and/or second compositions dispensed on the first major surface, such that a curable layer comprising the first and second compositions is formed between the first and second major surfaces.

### Optical Bonding Layer

In some embodiments, the optical bonding layer allows one to rework an optical assembly with little or no damage to components. The optical bonding layer can be used in optical assemblies comprising large display panels which may have an area of from about 15 cm² to about 5 m² or from about 15 cm² to about 1 m². For reworkability, the optical bonding layer may have a cleavage strength between glass substrates of about 15 N/mm or less, 10 N/mm or less, or 6 N/mm or less. Total energy to cleavage can be less than about 25 kg*mm over a 1″×1″ area.

In some embodiments, the optical bonding layer exhibits little or no delamination under normal use or conditions specified by standards depending on the particular industry. Industry standards which may need to be met include accelerated aging tests, for example, elevated temperature storage at 65° C. or 85° C. for a period of time between 300 and 1000 hours, or heat and humidity storage, for example, at 65° C. and 95% relative humidity for a period of time between 300 and 1000 hours.

In some embodiments, the optical bonding layer may be made using a liquid optically clear adhesive or liquid composition as the first and/or second compositions as described below. These types of liquid compositions have a viscosity suitable for efficient manufacturing of large optical assemblies. For example, the liquid composition may have a viscosity of from about 100 to about 140,000 cps, from about 100 to about 10,000 cps, from about 100 to about 5000 cps, from about 100 to about 1000 cps, from about 200 to about 700 cps, from about 200 to about 500 cps, or from about 500 to about 4000 cps wherein viscosity is measured for the composition at 25° C. and 1 sec⁻¹. The liquid compositions may have a viscosity of 18,000 cps to 140,000 cps for the composition at 25° C. and shear rate 1 sec⁻¹, and a viscosity of 700,000 cps to 4,200,000 cps for the composition at 25° C. and shear rate 0.01 sec⁻¹. The liquid composition is amenable for use in a variety of manufacturing methods.

In some embodiments, the optical bonding layer comprises a second composition substantially surrounding the first, and the viscosity of the second composition is less than that of the first. For example, the viscosity of the second composition may be less than 10 times that of the first, or less than 5 times that of the first.

The optical bonding layer may have one or more regions which are soft, for example, a central region having a Shore A hardness of less than about 30, less than about 20 or less than about 10.

The optical bonding layer may exhibit little or no shrinkage, e.g., less than about 5%, depending on whatever amount is acceptable.

The optical bonding layer has optical properties suitable for the intended application. For example, the optical bonding layer may have at least 85% transmission over the range of from 460 to 720 nm. The optical bonding layer may have, per millimeter thickness, a transmission of greater than about 85% at 460 nm, greater than about 90% at 530 nm, and greater than about 90% at 670 nm. These transmission characteristics provide for uniform transmission of light across the visible region of the electromagnetic spectrum which is important to maintain the color point if the display panel assembly is used in full color displays.

The optical bonding layer preferably has a refractive index that matches or closely matches that of the first and/or second optical substrates, e.g., from about 1.4 to about 1.7. In some embodiments, the refractive indices of the first and second regions are substantially the same. In some embodiments, the refractive indices of the first and second regions are different by less than 0.5, 0.2, 0.1 or 0.01.

The optical bonding layer may have any suitable thickness. The particular thickness employed in the display panel assembly may be determined by any number of factors, for example, the design of an optical device in which the display panel assembly is used may require a certain gap between the display panel and the other optical substrate. The optical bonding layer typically has a thickness of from about 1 um to about 12 mm, from about 1 um to about 5 mm, from about 50 um to about 2 mm, from about 50 um to about 1 mm, from about 50 um to about 0.5 mm, or from about 50 um to about 0.2 mm.

The first and/or second compositions used to make the optical bonding layer described herein may or may not be curable individually. At a minimum, the mixture of the first and second compositions must form a curable composition. When the curable layer between optical substrates is cured, an optical bonding layer is formed, the optical bonding layer having at least two regions with different physical properties.

Different physical properties of the optical bonding layer can comprise differences in the rates at which the cured regions are formed, differences in hardness of the two regions, differences in tack or level of adhesion between the two regions, and differences in moduli or elasticity. Differences in moduli may be defined as differences in the measured elastic modulus, Young′ modulus, and storage and loss modulus between the regions. Further, one or both of the two regions may be in liquid form after curing, and if both are liquids, the viscosities may be different.

In some embodiments, the optical bonding layer comprises a first region and a second region substantially surrounding the first region, wherein the hardness of the second region is greater than that of the first. In some embodiments, the first and second regions are tacky. In some embodiments, the first region is tacky, and the second is not. In some embodiments, the optical bonding layer may be a gel or an elastomer, meaning that one or both regions may have these properties.

Nanoindentation is one useful way to measure differences in the properties of small and thin regions of the optical bonding layer. Nanoindentation can measure differences in the modulus of elasticity and hardness. Differences in tack or the tackiness of the at least two regions can be determined by qualitative means such as physical touching of a tissue to the two different regions and looking at the differences in the amount of fibers transferred to the region of the optical from the tissue. Differences in tack or tackiness of the at least two regions can be measured quantitatively using equipment such as a probe tack tester.

Any type of electromagnetic radiation may be used to cure the curable composition which forms the optical bonding layer. In some embodiments, the first and second compositions are formulated so that curing may be carried out by one or more curing means. Any one or combination of curing means may be used such as UV radiation (200-400 nm), actinic radiation (700 nm or less), near-IR radiation (700-1500 nm), heat, and/or electron beam. Actinic radiation is radiation that leads to the production of photochemical activity. For example, actinic radiation may comprise radiation of from about 250 to about 700 nm. Sources of actinic radiation include tungsten halogen lamps, xenon and mercury arc lamps, incandescent lamps, germicidal lamps, fluorescent lamps, lasers and light emitting diodes. UV-radiation can be supplied using a high intensity continuously emitting system such as those available from Fusion UV Systems.

In some embodiments, one or both of the optical substrates may have an opaque, colored or black border that may cover the second composition that is surrounding the first composition, for example, as shown in FIGS. 2B, 4C and 5F. In these cases, the border may block actinic radiation from reaching the covered region containing the second composition and may affect the ability to cure the second region. For such situations, alternative additives and/or catalysts may be required to cure the second composition, and/or a combination of curing means may be used. For example, if one or both optical substrates has an opaque, colored or black border that covers the second composition that is surrounding the first composition, actinic radiation may be used, followed by application of heat to cure any part of the curable layer not accessible by the actinic radiation because of the border.

In some embodiments, actinic radiation may be applied to the first and/or second compositions in order to partially polymerize the compositions. The first and/or second compositions may be disposed between the display panel and the substantially transparent substrate and then partially polymerized. The first and/or second compositions may be disposed on the display panel or the substantially transparent substrate and partially polymerized, then the other of the display panel and the substrate may be disposed on the partially polymerized layer.

In some embodiments, actinic radiation may be applied to a layer of the first and/or second compositions in order to completely or nearly completely polymerize the compositions. The first and/or second compositions may be disposed between the display panel and the substantially transparent substrate and then completely or nearly completely polymerized. The first and/or second compositions may be disposed on the display panel or the substantially transparent substrate and completely or nearly completely polymerized, then the other of the display panel and the substrate may be disposed on the polymerized layer.

The first composition comprises a first ethylenically unsaturated compound having at least one ethylenically unsaturated group. The first ethylenically unsaturated compound may be a multifunctional (meth)acrylate oligomer. In general, (meth)acrylate refers to both acrylate and methacrylate functionality. The multifunctional (meth)acrylate oligomer comprising any one or more of: a multifunctional urethane (meth)acrylate oligomer, a multifunctional polyester (meth)acrylate oligomer, and a multifunctional polyether (meth)acrylate oligomer. The multifunctional (meth)acrylate oligomer may comprise at least two (meth)acrylate groups, e.g., from 2 to 4 (meth)acrylate groups, that participate in polymerization during curing.

The multifunctional (meth)acrylate oligomer may comprise a multifunctional urethane (meth)acrylate oligomer having at least two (meth)acrylate groups, e.g., from 2 to 4 (meth)acrylate groups, that participate in polymerization during curing. In general, these oligomers comprise the reaction product of a polyol with a multifunctional isocyanate, followed by termination with a hydroxy-functionalized (meth)acrylate. For example, the multifunctional urethane (meth)acrylate oligomer may be formed from an aliphatic polyester or polyether polyol prepared from condensation of a dicarboxylic acid, e.g., adipic acid or maleic acid, and an aliphatic diol, e.g. diethylene glycol or 1,6-hexane diol. In one embodiment, the polyester polyol comprises adipic acid and diethylene glycol. The multifunctional isocyanate may comprise methylene dicyclohexylisocyanate or 1,6-hexamethylene diisocyanate. The hydroxy-functionalized (meth)acrylate may comprise a hydroxyalkyl (meth)acrylate such as 2-hydroxyethyl acrylate, 2-hydroxypropyl (meth)acrylate, 4-hydroxybutyl acrylate, or polyethylene glycol (meth)acrylate. In one embodiment, the multifunctional urethane (meth)acrylate oligomer comprises the reaction product of a polyester polyol, methylene dicyclohexylisocyanate, and hydroxyethyl acrylate.

Useful multifunctional urethane (meth)acrylate oligomers include products that are commercially available. For example, the multifunctional aliphatic urethane (meth)acrylate oligomer may comprise urethane diacrylate CN9018, CN3108, and CN3211 available from Sartomer, Co., Exton, Pa., GENOMER 4188/EHA (blend of GENOMER 4188 with 2-ethylhexyl acrylate), GENOMER 4188/M22 (blend of GENOMER 4188 with GENOMER 1122 monomer), GENOMER 4256, and GENOMER 4269/M22 (blend of GENOMER 4269 and GENOMER 1122 monomer) available from Rahn USA Corp., Aurora Ill.; U-Pica 8966, 8967, 8967A and combinations thereof, available from Japan U-Pica Corp., and polyether urethane diacrylate BR-3042, BR-3641AA, BR-3741AB, and BR-344 available from Bomar Specialties Co., Torrington, Conn.

The multifunctional (meth)acrylate oligomer may comprise a multifunctional polyester (meth)acrylate oligomer. Useful multifunctional polyester acrylate oligomers include products that are commercially available. For example, the multifunctional polyester acrylate may comprise BE-211 available from Bomar Specialties Co. and CN2255 available from Sartomer Co.

The multifunctional (meth)acrylate oligomer may comprise a multifunctional polyether (meth)acrylate oligomer. Useful multifunctional polyether acrylate oligomers include products that are commercially available. For example, the multifunctional polyether acrylate may comprise Genomer 3414 available from Rahn USA Corp.

Other oligomers that are useful in the first composition include multifunctional polybutadiene (meth)acrylate oligomers such as difunctional polybutadiene (meth)acrylate oligomer CN307 available from Sartomer Co.; and methacrylated isoprene oligomers UC-102 and UC-203 available from Kuraray America, Inc.

Liquid rubber may also be used such as LIR-30 liquid isoprene rubber and LIR-390 liquid butadiene/isoprene copolymer rubber available from Kuraray, Inc. and Ricon 130 liquid polybutadiene rubber available from Sartomer Co., Inc.

The particular multifunctional (meth)acrylate oligomer used in the first composition, as well as the amount used in the first composition, may depend on a variety of factors such as the desired properties of the first composition and/or the optical bonding layer. For example, the particular multifunctional (meth)acrylate oligomer and/or the amount used in the first composition may be selected such that the first composition is a liquid composition having a viscosity of from about 100 to about 140,000 cps, from about 100 to about 10,000 cps, from about 100 to about 5000 cps, from about 100 to about 1000 cps, from about 200 to about 700 cps, from about 200 to about 500 cps, or from about 500 to about 4000 cps wherein viscosity is measured for the composition at 25° C. and 1 sec⁻¹. For another example, the particular multifunctional (meth)acrylate oligomer and/or the amount thereof may be selected such that the first composition is a liquid composition having a viscosity of from about 100 to about 1000 cps, and the resulting optical bonding layer has a Shore A hardness of less than about 30, or less than about 20. Regions of the optical bonding layer formed from the first composition may comprise from about 15 to about 50 wt. %, from about 20 to about 60 wt. %, or from about 20 to about 45 wt. %, of the multifunctional (meth)acrylate oligomer.

For yet another example, the particular oligomer and/or the amount thereof may be selected such that the adhesive composition is a liquid composition having a viscosity of 18,000 cps to 140,000 cps for the composition at 25° C. and shear rate 1 sec⁻¹, and a viscosity of 700,000 cps to 4,200,000 cps for the composition at 25° C. and shear rate 0.01 sec⁻¹.

The first ethylenically unsaturated compound may comprise a reactive diluent comprising a monofunctional (meth)acrylate monomer having a viscosity of from about 4 to about 20 cps at 25° C. The reactive diluent may comprise more than one monomer, for example, from 2-5 different monomers. Examples of these monomers include isobornyl acrylate, isobornyl (meth)acrylate, tetrahydrofurfuryl acrylate, tetrahydrofurfuryl methacrylate, alkoxylated tetrahydrofurfuryl acrylate, alkoxylated methacrylate, tetrahydrofurfuryl methacrylate and mixtures thereof. For example, the reactive diluent may comprise tetrahydrofurfuryl (meth)acrylate and isobornyl (meth)acrylate. For another example, the reactive diluent may comprise alkoxylated tetrahydrofurfuryl acrylate and isobornyl acrylate.

The first ethylenically unsaturated compound may comprise a reactive diluent comprising compounds described in U.S. Pat. No. 5,545,676, including di-, and poly-acrylates and methacrylates (for example, hexanediol diacrylate, glycerol diacrylate, glycerol triacrylate, ethyleneglycol diacrylate, diethyleneglycol diacrylate, triethyleneglycol dimethacrylate, 1,3-propanediol diacrylate, 1,3-propanediol dimethacrylate, trimethylolpropane triacrylate, 1,2,4-butanetriol trimethacrylate, 1,4-cyclohexanediol diacrylate, pentaerythritol triacrylate, pentaerythritol tetraacrylate, pentaerythritol tetramethacrylate, sorbitol hexacrylate, bis[1-(2-acryloxy)]-p-ethoxyphenyldimethylmethane, bis[1-(3-acryloxy-2-hydroxy)]-p-propoxyphenyldimethylmethane, tris-hydroxyethyl-isocyanurate trimethacrylate, the bis-acrylates and bis-methacrylates of polyethylene glycols of molecular weight about 200-500, copolymerizable mixtures of acrylated monomers such as those described in U.S. Pat. No. 4,652,274, and acrylated oligomers such as those described in U.S. Pat. No. 4,642,126); unsaturated amides (for example, methylene bis-acrylamide, methylene bis-methacrylamide, 1,6-hexamethylene bis-acrylamide, diethylene triamine tris-acrylamide and beta-methacrylaminoethyl methacrylate); vinyl compounds (for diallyl phthalate, divinyl succinate, divinyl adipate, and divinyl phthalate); and the like; and mixtures thereof.

The reactive diluent may comprise a monofunctional (meth)acrylate monomer having alkylene oxide functionality. This monofunctional (meth)acrylate monomer having alkylene oxide functionality may comprise more than one monomer. Alkylene functionality includes ethylene glycol and propylene glycol. The glycol functionality is comprised of units, and the monomer may have anywhere from 1 to 10 alkylene oxide units, from 1 to 8 alkylene oxide units, or from 4 to 6 alkylene oxide units. The monofunctional (meth)acrylate monomer having alkylene oxide functionality may comprise propylene glycol monoacrylate available as Bisomer PPA6 from Cognis Ltd. This monomer has 6 propylene glycol units. The monofunctional (meth)acrylate monomer having alkylene oxide functionality may comprise ethylene glycol monomethacrylate available as Bisomer MPEG350MA from Cognis Ltd. This monomer has on average 7.5 ethylene glycol units.

The reactive diluent may comprise a monofunctional (meth)acrylate monomer having pendant alkyl groups of from 4 to 20 carbon atoms, e.g., 2-ethylhexyl acrylate, lauryl acrylate, isodecyl acrylate, and stearyl acrylate.

The particular reactive diluent used in the first composition, as well as the amount used in the first composition, may depend on a variety of factors such as the desired properties of the first composition and/or the optical bonding layer. For example, the particular reactive diluent and/or the amount used in the first composition may be selected such that the first composition is a liquid composition having a viscosity of from about 100 to about 140,000 cps, from about 100 to about 10,000 cps, from about 100 to about 5000 cps, from about 100 to about 1000 cps, from about 200 to about 700 cps, from about 200 to about 500 cps, or from about 500 to about 4000 cps wherein viscosity is measured for the composition at 25° C. and 1 sec⁻¹. For another example, the particular multifunctional (meth)acrylate oligomer and/or the amount thereof may be selected such that the first composition is a liquid composition having a viscosity of from about 100 to about 1000 cps, and the resulting optical bonding layer has a Shore A hardness of less than about 30, or less than about 20. The optical bonding layer formed from the first composition may comprise from about 15 to about 50 wt. %, from about 30 to about 60 wt. %, or from about 40 to about 60 wt. %, of the reactive diluent, relative to the total weight of the optical bonding layer. Regions of optical bonding layer formed from the first composition may comprise from about 5 to about 30 wt. %, or from about 10 to about 20 wt. %, of the monofunctional (meth)acrylate monomer having alkylene oxide functionality.

For yet another example, the particular diluent and/or the amount thereof may be selected such that the adhesive composition is a liquid composition having a viscosity of 18,000 cps to 140,000 cps for the composition at 25° C. and shear rate 1 sec⁻¹ and a viscosity of 700,000 cps to 4,200,000 cps for the composition at 25° C. and shear rate 0.01 sec⁻¹.

The second composition comprises a second ethylenically unsaturated compound having at least two ethylenically unsaturated groups, and the second ethylenically unsaturated compound is different from the first. The second ethylenically unsaturated compound may be a multifunctional (meth)acrylate oligomer as described above for the first ethylenically unsaturated compound. The second ethylenically unsaturated compound may be a reactive diluent as described above for the first ethylenically unsaturated compound. The particular reactive diluent used in the second composition, as well as the amount used in the second composition, may depend on a variety of factors such as the desired properties of the second composition and/or the optical bonding layer.

In some embodiments, the first composition comprises the second ethylenically unsaturated compound. The concentration of the second ethylenically unsaturated compound in the second composition is greater than the concentration of the second ethylenically unsaturated compound in the first composition,

In some embodiments, the first composition further comprises a third ethylenically unsaturated compound having at least two ethylenically unsaturated groups, and the third ethylenically unsaturated compound is different from the first and second ethylenically unsaturated compounds. In some embodiments, the second ethylenically unsaturated compound has more ethylenically unsaturated groups per molecule than the third ethylenically unsaturated compound. In cases where the first composition comprises the third ethylenically unsaturated compound, the concentration of ethylenically unsaturated groups in the second composition is greater than that of the ethylenically unsaturated groups in the first composition. The third ethylenically unsaturated compound may be a multifunctional (meth)acrylate oligomer as described above for the first ethylenically unsaturated compound. The third ethylenically unsaturated compound may be a reactive diluent as described above for the first ethylenically unsaturated compound. The particular third ethylenically unsaturated compound used in the first composition, as well as the amount used in the first composition, may depend on a variety of factors such as the desired properties of the first composition and/or the optical bonding layer.

In some embodiments, the first and/or second compositions comprise a plasticizer in order to increase the softness and flexibility of the optical bonding layer. Plasticizers are well known and typically do not participate in polymerization of ethylenically unsaturated groups. The plasticizer may comprise more than one plasticizer material. The plasticizer may comprise an oil. Suitable oils include vegetable oil, mineral oil and soybean oil. The particular plasticizer used, as well as the amount used, may depend on a variety of factors such as desired viscosity of the first composition and/or optical bonding layer. The optical bonding layer may comprise from greater than 5 to about 20 wt. %, or from greater than 5 to about 15 wt. %, of the plasticizer.

In some embodiments, the first and/or second compositions comprise a tackifier in order to increase the tack or other properties of the optical bonding layer. There are many different types of tackifiers but nearly any tackifier can be classified as: a rosin resin derived from wood rosin, gum rosin or tall oil rosin; a hydrocarbon resin made from a petroleum based feedstock; or a terpene resin derived from terpene feedstocks of wood or certain fruits. The particular tackifier used, as well as the amount used, may depend on a variety of factors such as desired viscosity of the first composition and/or optical bonding layer. The tackifier and/or the amount thereof may be selected such that the optical bonding layer has a cleavage strength between glass substrates of about 15 N/mm or less, 10 N/mm or less, or 6 N/mm or less. The optical bonding layer may comprise, e.g., from 0.01 to about 20 wt. %, from 0.01 to about 15 wt. %, or from 0.01 to about 10 wt. % of tackifier. The optical bonding layer may be substantially free of tackifier comprising, e.g., from 0.01 to about 5 wt. % or from about 0.01 to about 0.5 wt. % of tackifier all relative to the total weight of the optical bonding layer. The optical bonding layer may be free of tackifier.

In some embodiments, the first composition comprises: the reaction product of from about 20 to about 60 wt. % of multifunctional (meth)acrylate oligomer, and from about 30 to about 60 wt. % of reactive diluent comprising a monofunctional (meth)acrylate monomer having a viscosity of from about 4 to about 20 cps at 25° C.; and from greater than 5 to about 25 wt. % plasticizer. The multifunctional (meth)acrylate oligomer may comprise any one or more of: multifunctional urethane (meth)acrylate oligomer, a multifunctional polyester (meth)acrylate oligomer, and a multifunctional polyether (meth)acrylate oligomer. The monofunctional (meth)acrylate monomer may comprise a tetrahydrofurfuryl (meth)acrylate and isobornyl (meth)acrylate. The tetrahydrofurfuryl (meth)acrylate may comprise an alkoxylated tetrahydrofurfuryl acrylate. The plasticizer may comprise oil. The reaction product may further comprise a monofunctional (meth)acrylate monomer having alkylene oxide functionality. This first composition may be substantially free of tackifier. An optical bonding layer formed from this first composition can have a cleavage strength between glass substrates of about 15 N/mm or less. A tackified resin may also be included in any of these adhesive layers.

In some embodiments, the first composition comprises: the reaction product of from about 20 to about 60 wt. % multifunctional (meth)acrylate oligomer, and from about 40 to about 80 wt. % reactive diluent comprising a monofunctional (meth)acrylate monomer having a viscosity of from about 4 to about 20 cps at 25° C., and a monofunctional (meth)acrylate monomer having alkylene oxide functionality. The multifunctional (meth)acrylate oligomer may comprise any one or more of: a multifunctional urethane (meth)acrylate oligomer, a multifunctional polyester (meth)acrylate oligomer, and a multifunctional polyether (meth)acrylate oligomer. The monofunctional (meth)acrylate monomer having a viscosity of from about 4 to about 20 cps at 25° C. may comprise a tetrahydrofurfuryl (meth)acrylate and isobornyl (meth)acrylate, and the monofunctional (meth)acrylate monomer having alkylene oxide functionality may have from 1 to 10 alkylene oxide units. The tetrahydrofurfuryl (meth)acrylate may comprise an alkoxylated tetrahydrofurfuryl acrylate. This optical bonding layer may be substantially free of tackifier. This optical bonding layer may comprise a glass-to-glass cleavage force of about 15 N/mm or less.

In some embodiments, one or more regions of the optical bonding layer comprises the reaction product of: from about 20 to about 60 wt. % multifunctional rubber-based (meth)acrylate oligomer, and from about 20 to about 60 wt. % monofunctional (meth)acrylate monomer having a pendant alkyl group of from 4 to 20 carbon atoms; and from greater than 5 to about 25 wt. % liquid rubber. The multifunctional rubber-based (meth)acrylate oligomer may comprise any one or more of: a multifunctional polybutadiene (meth)acrylate oligomer, a multifunctional isoprene (meth)acrylate oligomer, and a multifunctional (meth)acrylate oligomer comprising a copolymer of butadiene and isoprene. The liquid rubber may comprise liquid isoprene. This optical bonding layer may comprise little or no tackifier, or the layer may be substantially free of tackifier. This optical bonding layer may comprise a plasticizer and/or an oil. This optical bonding layer may comprise a glass-to-glass cleavage force of about 15 N/mm or less.

The adhesive layer may comprise: the reaction product of from about 20 to about 50 wt. % of the multifunctional rubber-based (meth)acrylate oligomer, and from about 20 to about 50 wt. % of the monofunctional (meth)acrylate monomer having a pendant alkyl group of from 4 to 20 carbon atoms; and from greater than 5 to about 25 wt. % of the liquid rubber.

In some embodiments, the first and second compositions comprise the following. The first composition comprises a multifunctional urethane diacrylate; alkoxylated tetrahydrofuranyl acrylate; isobornyl acrylate; ethyl-2,4,6-trimethylbenzoylphenylphosphinate; polypropylene glycol monoacrylate; and soybean oil. The second composition comprises hexanediol diacrylate.

In some embodiments, the first and second compositions comprise the following. The first composition comprises a multifunctional urethane diacrylate; alkoxylated tetrahydrofuranyl acrylate; isobornyl acrylate; ethyl-2,4,6-trimethylbenzoylphenylphosphinate; polypropylene glycol monoacrylate; and soybean oil. The second composition comprises hexanediol diacrylate and ethyl-2,4,6-trimethylbenzoylphenylphosphinate.

In some embodiments, the first and second compositions comprise the following. The first composition comprises 2-ethylhexyl acrylate, acrylic acid, and photoinitiator. The second composition comprises 2-ethylhexyl acrylate, acrylic acid, 1,6-hexanediol diacrylate, and photoinitiator.

In general, the optical bonding layer may comprise spacer beads in order to “set” a particular thickness of the layer. The spacer beads may comprise ceramic, glass, silicate, polymer, or plastic. The spacer beads are generally spherical and have a diameter of from about 1 um to about 5 mm, from about 50 um to about 1 mm, or from about 50 um to about 0.2 mm.

In general, the optical bonding layer may comprise nonabsorbing metal oxide particles, for example, to modify the refractive index of the optical bonding layer or the viscosity of the liquid adhesive composition (as described herein). Nonabsorbing metal oxide particles that are substantially transparent may be used. For example, a 1 mm thick disk of the nonabsorbing metal oxide particles in an optical bonding layer may absorb less than about 15% of the light incident on the disk. Examples of nonabsorbing metal oxide particles include clay, Al₂O₃, ZrO₂, TiO₂, V₂O₅, ZnO, SnO₂, ZnS, SiO₂, and mixtures thereof, as well as other sufficiently transparent non-oxide ceramic materials. The metal oxide particles can be surface treated to improve dispersibility in the optical bonding layer and the composition from which the layer is coated. Examples of surface treatment chemistries include silanes, siloxanes, carboxylic acids, phosphonic acids, zirconates, titanates, and the like. Techniques for applying such surface treatment chemistries are known. Organic fillers such as cellulose, castor-oil wax and polyamide-containing fillers may also be used.

In some embodiments, the liquid optically clear adhesive comprises fumed silica. Suitable fumed silicas include AEROSIL 200; and AEROSIL R805 (both available from Evonic Industries); CAB-O-SIL TS 610; and CAB-O-SIL T 5720 (both available from Cabot Corp.), and HDK H2ORH (available from Wacker Chemie AG).

In some embodiments, the liquid optically clear adhesive comprises clay such as GARAMITE 1958 (available from Southern Clay Products).

Nonabsorbing metal oxide particles may be used in an amount needed to produce the desired effect, for example, in an amount of from about 2 to about 10 wt. %, from about 3.5 to about 7 wt. %, from about 10 to about 85 wt. %, or from about 40 to about 85 wt. %, based on the total weight of the optical bonding layer. Nonabsorbing metal oxide particles may only be added to the extent that they do not add undesirable color, haze or transmission characteristics. Generally, the particles can have an average particle size of from about 1 nm to about 100 nm.

In some embodiments, the adhesive layer may be formed from a thixotropic liquid optically clear adhesive. As used herein, a composition is considered thixotropic if the composition shear thins, i.e., viscosity decreases when the composition is subjected to a shearing stress over a given period of time with subsequent recovery or partial recovery of viscosity when the shearing stress is decreased or removed. Such adhesives exhibit little or no flow under zero or near-zero stress conditions. The advantage of the thixotropic property is that the adhesive can be dispensed easily by such processes as needle dispensing due to the rapid decrease in viscosity under low shear rate conditions. The main advantage of thixotropic behavior over simply high viscosity is that high viscosity adhesive is difficult to dispense and to flow during application. Adhesive compositions can be made thixotropic by adding particles to the compositions. In some embodiments, fumed silica is added to impart thixotropic properties to a liquid adhesive, in an amount of from about 2 to about 10 wt. %, or from about 3.5 to about 7 wt. %.

In some embodiments, the viscosities of the liquid optically clear adhesive may be controlled at two or more different shear rates. For example, the liquid optically clear adhesive may have a viscosity of greater than 10,000 cps to about 140,000 cps for the composition at 25° C. and shear rate 1 sec⁻¹, preferably from 18,000 cps to 140,000 cps for the composition at 25° C. and shear rate 1 sec⁻¹, and a viscosity of 700,000 cps to 4,200,000 cps for the composition at 25° C. and shear rate 0.01 sec⁻¹.

In some embodiments, the liquid optically clear adhesive has a displacement creep of about 0.1 radians or less when a stress of 10 Pa is applied to the adhesive for 2 minutes. In general, displacement creep is a value determined by using an AR2000 Rheometer manufactured by TA Instruments and a 40 mm diameter×1° cone at 25° C., and is defined as the rotational angle of the cone when a stress of 10 Pa is applied to the adhesive.

Generally, initiators are materials which initiate the chemical reaction that causes the (meth)acrylate resin to cure. Promoters and accelerators are used to speed up and enhance the cure. Retarders are used to extend gel time.

Four classes of initiator widely used in free radical polymerization are well documented: azo initiators (Sheppard C S, Azo compounds, in Encyclopedia of Polymer Science and Engineering, ed. by Mark H F, Bikales N M, Overberger C G and Menges G. Wiley-Interscience, New York, pp. 143-157 (1985)); peroxide initiators (Sheppard C S, Peroxy compounds, in Encyclopedia of Polymer Science and Engineering, ed. by Mark H F, Bikales N M, Overberger C G and Menges G. Wiley-Interscience, New York, pp. 1-21 (1988)); disulfide initiators (Oda T, Maeshima T and Sugiyama K, Markromol. Chem. 179:2331-2336 (1978)); and redox initiators (Sarac A S, Prog. Polym. Sci. 24:1149-1204 (1999)). A prime advantage of redox initiators is that their relatively low activation energy can result in radical production at reasonable rates over a very wide range of temperatures, depending on the particular redox system, including initiation at moderate temperatures of 0-50° C. and even lower (Odian G, Radical chain polymerization, in Principles of Polymerization, 4th edition. Wiley-Interscience, Hoboken, N.J., pp. 198-349 (2004)). A number of redox reactions, including both inorganic and organic components either wholly or in part, may be employed for this purpose.

Of particular use are redox systems consisting of an initiator, a promoter, and an accelerator and optionally a retarder. Examples of preferred initiators are peroxides, including benzoyl peroxide, cumene hydroperoxide, and methyl ethyl ketone peroxide. The peroxide may be used at a level of 0.5 to 5 wt. % based on total weight of the composition.

Examples of preferred promoters are cobalt(II) naphthenate, vanadium(III) acetyl acetonate, copper(II) 2-ethylhexanoate, and vanadium(III) naphthenate. The promoter may be used at a level of 0.2 to 2 wt % based on total weight of the composition. A preferred ratio of peroxide to promoter is 3:1 up to 10:1.

Examples of accelerators are N,N-dimethylaniline, N,N-diethylaniline, N,N dimethylacetoacetonate, and 4,N,N-trimethylaniline. The accelerator may be used at a level of 0.1 to 1 wt. % based on total weight of the composition.

The first and/or second compositions comprise a catalyst. Useful catalysts include photoinitiators when curing with UV-radiation. Photoinitiators include organic peroxides, azo compounds, quinines, nitro compounds, acyl halides, hydrazones, mercapto compounds, pyrylium compounds, imidazoles, chlorotriazines, benzoin, benzoin alkyl ethers, ketones, phenones, and the like. For example, the adhesive compositions may comprise ethyl-2,4,6-trimethylbenzoyl-phenylphosphinate available as LUCIRIN TPO-L from BASF Corp. or 1-hydroxy-cyclohexyl phenyl ketone available as IRGACURE 184 from Ciba Specialty Chemicals. The photoinitiator is often used at a concentration of about 0.1 to 10 weight percent or 0.1 to 5 wt. % based on the weight of oligomeric and monomer material in the polymerizable composition.

Each of the first composition, second composition and optical bonding layer can optionally include one or more additives such as chain transfer agents, antioxidants, stabilizers, fire retardants, viscosity modifying agents, antifoaming agents, antistats, wetting agents, colorants such as dyes and pigments, fluorescent dyes and pigments, phosphorescent dyes and pigments, fibrous reinforcing agents, and woven and non-woven fabrics.

### General Preparation of Optical Assembly

In the assembly process, it is generally desirable to have a layer of liquid composition that is substantially uniform. The two components are held securely in place. If desired, uniform pressure may be applied across the top of the assembly. If desired, the thickness of the layer may be controlled by a gasket, standoffs, shims, and/or spacers used to hold the components at a fixed distance to each other. Masking may be required to protect components from overflow. Trapped pockets of air may be prevented or eliminated by vacuum or other means. Radiation may then be applied to form the optical bonding layer.

The display panel assembly may be prepared by creating an air gap or cell between the two components and then disposing the liquid composition into the cell. An example of this method is described in U.S. Pat. No. 6,361,389 B1 (Hogue et. al) and includes adhering together the components at the periphery edges so that a seal along the periphery creates the air gap or cell. Adhering may be carried out using any type of adhesive, e.g., a bond tape such as a double-sided pressure sensitive adhesive tape, a gasket, an RTV seal, etc., as long as the adhesive does not interfere with reworkability as described above. Then, the liquid composition is poured into the cell through an opening at a periphery edge. Alternatively, the liquid composition is injected into the cell maybe using some pressurized injection means such as a syringe. Another opening is required to allow air to escape as the cell is filled. Exhaust means such as vacuum may be used to facilitate the process. Actinic radiation may then be applied as described above to form the optical bonding layer.

The optical assembly may be prepared using an assembly fixture such as the one described in U.S. Pat. No. 5,867,241 (Sampica et al.) In this method, a fixture comprising a flat plate with pins pressed into the flat plate is provided. The pins are positioned in a predetermined configuration to produce a pin field which corresponds to the dimensions of the display panel and of the component to be attached to the display panel. The pins are arranged such that when the display panel and the other components are lowered down into the pin field, each of the four corners of the display panel and other components is held in place by the pins. The fixture aids assembly and alignment of the components of an display panel assembly with suitable control of alignment tolerances. Additional embodiments of this assembly method are described in Sampica et al. U.S. Pat. No. 6,388,724 B 1 (Campbell, et. al) describes how standoffs, shims, and/or spacers may be used to hold components at a fixed distance to each other.

### Optical Components

The display panel assembly disclosed herein may comprise additional components typically in the form of layers. For example, a heating source comprising a layer of indium tin oxide or another suitable material may be disposed on one of the components. Additional components are described in, for example, US 2008/0007675 A1 (Sanelle et al.).

The display panel may comprise any type of panel such as a liquid crystal display panel. Liquid crystal display panels are well known and typically comprise a liquid crystal material disposed between two substantially transparent substrates such as glass or polymer substrates. As used herein, substantially transparent refers to a substrate that is suitable for optical applications, e.g., has at least 85% transmission over the range of from 460 to 720 nm. Optical substrates may have, per millimeter thickness, a transmission of greater than about 85% at 460 nm, greater than about 90% at 530 nm, and greater than about 90% at 670 nm. On the inner surfaces of the substantially transparent substrates are transparent electrically conductive materials that function as electrodes. In some cases, on the outer surfaces of the substantially transparent substrates are polarizing films that pass essentially only one polarization state of light. When a voltage is applied selectively across the electrodes, the liquid crystal material reorients to modify the polarization state of light, such that an image is created. The liquid crystal display panel may also comprise a liquid crystal material disposed between a thin film transistor array panel having a plurality of thin film transistors arranged in a matrix pattern and a common electrode panel having a common electrode.

The display panel may comprise a plasma display panel. Plasma display panels are well known and typically comprise an inert mixture of noble gases such as neon and xenon disposed in tiny cells located between two glass panels. Control circuitry charges electrodes within the panel which causes the gases to ionize and form a plasma which then excites phosphors to emit light.

The display panel may comprise an organic electroluminescence panel. These panels are essentially a layer of an organic material disposed between two glass panels. The organic material may comprise an organic light emitting diode (OLED) or a polymer light emitting diode (PLED). These panels are well known.

The display panel may comprise an electrophoretic display. Electrophoretic displays are well known and are typically used in display technology referred to as electronic paper or e-paper. Electrophoretic displays comprise a liquid charged material disposed between two transparent electrode panels. Liquid charged material may comprise nanoparticles, dyes and charge agents suspended in a nonpolar hydrocarbon, or microcapsules filled with electrically charged particles suspended in a hydrocarbon material. The microcapsules may also be suspended in a layer of liquid polymer.

The substantially transparent substrate used in the display panel assembly may comprise a variety of types and materials. The substantially transparent substrate is suitable for optical applications and typically has at least 85% transmission over the range of from 460 to 720 nm. The substantially transparent substrate may have, per millimeter thickness, a transmission of greater than about 85% at 460 nm, greater than about 90% at 530 nm, and greater than about 90% at 670 nm.

The substantially transparent substrate may comprise glass or polymer. Useful glasses include borosilicate, sodalime, and other glasses suitable for use in display applications as protective covers. One particular glass that may be used comprises EAGLE XG™ and JADE™ glass substrates available from Corning Inc. Useful polymers include polyester films such as polyethylene terephalate, polycarbonate films or plates, acrylic films such as polymethylmethacrylate films, and cycloolefin polymer films such as ZEONOX and ZEONOR available from Zeon Chemicals L.P. The substantially transparent substrate preferably has an index of refraction close to that of display panel and/or the optical bonding layer; for example, from about 1.4 and about 1.7. The substantially transparent substrate typically has a thickness of from about 0.5 to about 5 mm.

The substantially transparent substrate may comprise a touch screen. Touch screens are well known and generally comprise a transparent conductive layer disposed between two substantially transparent substrates. For example, a touch screen may comprise indium tin oxide disposed between a glass substrate and a polymer substrate.

The optical assembly disclosed herein may be used in a variety of optical devices including, but not limited to, a phone, a television, a computer monitor, a projector, or a sign. The optical device may comprise a backlight for a display or lighting device.

### EXAMPLES

Materials used in the following examples are described in Table 1.

TABLE 1

| Abbreviation or | |
|---|---|
| Trade Name | Description |
| CN9018 | Urethane diacrylate (Sartomer Co., Exton, PA) |
| CD611 | Alkoxylated tetrahydrofuranyl Acrylate (Sartomer Co., Exton, PA) |
| SR506A | Isobornyl acrylate (Sartomer Co., Exton, PA) |
| TPO-L | Ethyl-2,4,6-trimethylbenzoylphenylphosphinate, photoinitiator |
| | (BASF Corp., Florham Park, NJ) |
| BISOMER PPA6 | Polypropylene glycol monoacrylate (Cognis Ltd., Southampton, UK) |
| Soybean oil | Plasticizer (Sigma-Aldrich Chem. Co., St. Louis, MO) |
| CN307 | Polybutadiene diacrylate (Sartomer Co., Exton, PA) |
| LIR-30 | Liquid isoprene rubber (Kuraray Co., Ltd, Tokyo JP) |
| NORSOCYL | 2-Ethylhexyl Acrylate (Arkema Inc., Philadelphia, PA) |
| 2-EHA | |
| 4812/75F | Lauryl Acrylate (Cognis Corp. USA, Cincinnati, OH) |
| SR335 | Lauryl Acrylate (Sartomer Co.) |
| 4-HBA | 4-Hydroxybutyl acrylate (BASF Corp.) |
| JONCRYL 960 | Acrylic oligomer (BASF Corp.) |
| JONCRYL 963 | Acrylic oligomer (BASF Corp.) |
| KE311 | Rosin ester (Arakawa Chemical Ind., Ltd., Osaka, Japan) |
| SILQUEST A-174 | Methacryloxypropyltrimethoxy Silane |
| | (Momentive Performance Materials, Albany, NY) |
| SILQUEST A-187 | δ-Glycidoxypropyltrimethoxy Silane |
| | (Momentive Performance Materials, Albany, NY) |
| DAROCUR 4265 | 50% DAROCUR 1173 (2-Hydroxy-2-methyl-1-phenyl-propan-1-one); and |
| | 50% TPO (2,4,6-Trimethylbenzoyl-diphenyl-phosphineoxide) |
| | (BASF Corp.) |
| IRGACURE 184 | 1-Hydroxycyclohexyl phenyl ketone |
| | (Ciba Specialty Chemicals Corp., Tarrytown, NY) |
| TC6-33, Part A | Linear Polydimethylsiloxane Vinyl Copolymer |
| | (Siltech Corp., Toronto, Canada) |
| TC6-33, Part B | Linear Polydimethylsiloxane Vinyl Copolymer and Hydrogen Polysiloxane |
| | (Siltech Corp., Toronto, Canada) |
| TC-7-103 | Linear Polydimethylsiloxane Vinyl Copolymer and Hydrogen Polysiloxane |
| | (Siltech Corp., Toronto, Canada) |
| TMCP | (Trimethyl)methylcyclopentadienylplatinum (IV) |
| | (Strem Chemicals, Inc., Newburyport, MA) |
| U-PICA 8966 | Urethane methacrylate oligomer |
| | (Japan U-Pica Corp) |
| U-PICA 8967 | Urethane methacrylate oligomer |
| | (Japan U-Pica Corp) |
| U-PICA 8967A | Urethane methacrylate oligomer |
| | (Japan U-Pica Corp) |
| AEROSIL A200 | Fumed silica |
| | (Evonik Industries, Parsippany, NJ) |
| AEROSIL R805 | Fumed silica |
| | (Evonik Industries, Parsippany, NJ) |
| HDK H2ORH | Fumed silica |
| | (Wacker Chemie AG) |

### Preparation of Liquid Optically Clear Adhesives

Compositions for Comparative Examples 1-2 (C1-C2) and Examples 1-9 (Ex1-9) comprising liquid optically clear adhesives (LOCAs) were prepared according to Table 2 were prepared. For a given composition, the LOCA components were charged to a black mixing container, a Max 200 (about 100 cm³), from FlackTek Inc., Landrum, S.C., and mixed using a Hauschild Speedmixer™ DAC 600 FV, from FlackTek Inc., operating at 2200 rpm for 4 minutes.

TABLE 2

| Component | C1 | C2 | Ex1 | Ex2 | Ex3¹ | Ex4² | Ex5 | Ex6 | Ex7² | Ex8³ | Ex9⁴ |
|---|---|---|---|---|---|---|---|---|---|---|---|
| CN9018 | 35 | 33 | 31 | 39 | 29 | | | | | 40 | 49 |
| CD611 | 24 | 23 | 22 | 25 | 25 | | | | | 21 | 18 |
| SR506A | 40 | 38 | 36 | 20 | 20 | | | | | 17 | 14 |
| TPO-L | 1 | 1 | 1 | 1 | 1 | | 0.8 | 0.8 | | 1 | 1 |
| BISOMER | | | | 15 | 15 | | | | | 13 | 11 |
| PPA6 | | | | | | | | | | | |
| Soybean oil | | 5 | 10 | | 10 | | 16.4 | | | 8.5 | 7 |
| CN307 | | | | | | | 32.7 | 32.7 | | | |
| LIR-30 | | | | | | | 16.4 | 32.7 | | | |
| NORSOCRYL | | | | | | | 32.7 | | | | |
| 2-EHA | | | | | | | | | | | |
| 4812/75F | | | | | | | | 32.7 | | | |
| IRGACURE | | | | | | | 1 | 1 | | | |
| 184 | | | | | | | | | | | |
| TC6-33, | | | | | | 25 | | | | | |
| Part A | | | | | | | | | | | |
| TC6-33, | | | | | | 25 | | | | | |
| Part B | | | | | | | | | | | |
| TC-7-103 | | | | | | | | | 50.0 | | |
| TMCP 3.66% | | | | | | 0.08 | | | 0.08 | | |
| in toluene | | | | | | | | | | | |

¹viscosity of liquid composition = 600 cps
²amount of platinum metal per total composition = 36 ppm
³viscosity of liquid composition = 1300 cps
⁴viscosity of liquid composition = 3000 cps

### Hardness Measurement

Sample pucks were made by filling a four cavity mold with each of the LOCAs described above. The cavity size was 1″ diameter×0.25″ thick cut from an aluminum plate. The mold comprised three components; a glass base, a polyethylene terephalate release liner and the aluminum plate with cavities. The three elements of the mold, glass base, release liner and aluminum cavity were clamped together prior to filling with LOCA. The filled molds were exposed to UV radiation by passing each through a UV light system, a Model F300S equipped with a type H bulb and a model LC-6 conveyor system all from Fusion UV Systems, Inc, Gaithersburg, Md. The molds were run through the system 5 times at as speed of 4″/sec. The molds were then turned over and run an additional 5 times at as speed of 4″/sec through the light system, exposing the partially cured LOCA though the glass plate, to ensure complete cure of the LOCAs. The total UVA energy each side received was about 2,500 mJ/cm², as measured by UV Power Puck II available from EIT, Inc. Sterling, Va.

Hardness was measured with a Shore A Durometer from Rex Gauge Company, Inc. Buffalo Grove, Ill., immediately after the pucks cooled to room temperature for all the examples except for Examples 4 and 7, which were allowed to cure for a minimum of 16 hours at room temperature.

### Viscosity Measurement

Viscosity measurements were made by using an AR2000 Rheometer equipped with a 40 mm, 1° stainless steel cone and plate from TA Instruments, New Castle, Del. Viscosities were measured using a steady state flow procedure with a frequency from 0.01 to 25 sec⁻¹ with a 28 μm gap between cone and plate at 25° C. Viscosities are reported for compositions at 25° C. and shear rate 1 sec⁻¹.

### Cleavage Strength and Total Energy

Cleavage strength measurements were made using a modified ASTM D 1062-02 Cleavage Strength test method. LOCA was placed between standard 1″×3″ microscope slides over an overlapping area of 1 in² and a thickness of 5 mils using 5 mil ceramic spacer beads which were placed on the adhesive before laminating the two glass slides together. Lamination consisted of placing the second slide, by hand, on top of the first slide having the LOCA and beads, and manually applying pressure. The LOCA between the slides was cured for 10 seconds with an Omnicure 2000 high pressure Hg spot cure source (ca. 2500 mJ/cm² UVA energy) from EXFO Photonic Solutions, Inc., Mississauga, Ontario, Canada. The bonded glass slides were then bonded to offset aluminum blocks specified in ASTM D 1062-02, using 3M™ Scotch-Weld™ Epoxy Adhesive DP100 available from the 3M™ Company, St. Paul, Minn., and allowed to cure overnight before testing. This also allowed the 1-part silicone to cure (Ex4 and 7). Cleavage force was measured using an MTS Insight 30 EL Electromechanical Testing System, Eden Prairie, Minn. The crosshead speed was 2 inches/min at 72° F. Results are reported as maximum tear strength, i.e. cleavage strength, (N/mm) and total energy (kg*mm). Failure mode is reported as either adhesive or cohesive.

### Shrinkage Measurement

Percent volume shrinkage was measured using an Accupyc II 1340 Pycnometer from Micromeritics Instrument Corporation, Norcross, Ga. An uncured LOCA sample of known mass was placed in a silver vial of the pycnometer. The vial was placed in the pycnometer and the volume of the sample was measured and the density of the LOCA was determined based on the volume and mass of the sample. Sample mass was about 3.5 grams. The density of a cured LOCA sample was measured following the same procedure as that of the uncured. Cured LOCA samples were prepared by following a similar procedure as described for the measurement of hardness, except the mold was made from teflon plate and the cavity size was 3.27 mm thickness and 13.07 mm in diameter. Volume shrinkage was then calculated from the following equation:

{[(1/Avg Liquid Density)−(1/Avg Cured Density)]/(1/Avg Liquid Density)}×100%

### Reworkability Measurement

A qualitative determination of the ability to debond the LOCA, i.e. reworkability, from a glass slide was made by the following procedure. LOCA was placed on a 2″ by 3″ glass slide with 1 mm thickness. The LOCA thickness was maintained at 5 mils by using 5 mil ceramic spacer beads which were placed on the adhesive before laminating the two glass slides together. Lamination consisted of placing the second slide, by hand, on top of the first slide having LOCA and beads, and manually applying pressure. Curing of the LOCA followed the procedure described above for the hardness measurement. After curing, the samples were left over night at ambient conditions. Reworkability was determined by taking a razor blade edge, about 1.5″ in length and sliding it between the two glass slides, on the 2″ side of the glass slide, to initiate a cleavage of the cured LOCA. A manual force was applied to the razor blade to pry open the glass slides. The time to completely separate the two glass slides while applying the force was recorded. Additionally, whether or not the glass slide broke under the applied force was also recorded. The lower the time to debond the two glass plates is generally thought to correlate to improved reworkability. If the glass slide broke during the process, the remaining glass attached to the other slide was removed by a similar procedure. The total time to separate all the glass was reported. The lower the time to completely debond the two glass plates was generally thought to correlate to improved reworkability. Additionally, the debonding mode, whether or not the glass broke and to what extend, was also monitored and reported.

TABLE 3

| | | | Cleavage | Total | | |
|---|---|---|---|---|---|---|
| | Shore A | Visc. | Strength | energy | Failure | Shrinkage |
| Ex. | Hardness | (cps) | (N/mm) | (kg*mm) | mode | (% Vol) |
| C1 | 8 | 638 | 49.9 | 103.9 | adhesive | 9.1 |
| C2 | <2¹ | 613 | 17.8 | 40.8 | adhesive | 5.4 |
| Ex1 | 8 | 1250 | 10.1 | 10.2 | adhesive | 4.6 |
| Ex2 | <2¹ | 543 | 9.9 | 25.6 | adhesive | 4.4 |
| Ex3 | <2¹ | 570 | 6.9 | 18.7 | adhesive | 4.0 |
| Ex4 | 8-10 | 3500 | 5.3 | 23.1 | cohesive | 2.6 |
| Ex5 | 3-4 | 270 | 2.0 | 1.6 | adhesive | 2.92 |
| Ex6 | 9 | 1460 | 5.6 | 3.4 | adhesive | 2.65 |
| Ex7 | <2¹ | 340 | 3.89 | 7.6 | cohesive | 1.34 |

¹<2 indicates the sample hardness was not measurable on the shore A hardness scale. This value is an estimate.

TABLE 4

| Ex. | Time to Debond | Debonding Mode |
|---|---|---|
| C1 | >10 min | Both glass slides severely broken |
| C2 | >10 min | Both glass slides severely broken |
| Ex1 | 2 min, 10 sec | Removed without breakage |
| Ex2 | 1 min, 50 sec | Removed without breakage |
| Ex3 | 3 min, 10 sec | Top glass slide broken into several pieces |
| Ex4 | 7 min, 20 sec | Top glass slide broken into several pieces |
| Ex5 | 20 sec | Removed without breakage |
| Ex6 | 20 sec | Top glass broke once |
| Ex7 | 20 sec | Removed without breakage |

### Rework of Assemblies

To facilitate cleaning of partially cured and uncured LOCAs remaining on the surface of a cover sheet and/or LCD panel, the separated components were fully cured using appropriate curing conditions. Cured LOCA can be removed by stretch release due to its elastic property. Residual cured LOCA can be removed by applying pressure sensitive adhesive tape over the cover sheet and LCD panel. Residual cured LOCA can also be removed by placing a cylindrical rod over the residual cured LOCA on the cover sheet and LCD panel.

Fully cured assemblies of a cover sheet and LCD panel can be separated by inserting a taut wire of e.g., stainless steel, glass fibre or nylon, with diameter slightly less than the gap size between the two components. The taut wire can then be passed through the two components by pulling the wire tightly up against and side of one of the components. This forces the wire to conform and exert a pressure on the surface of the cover sheet, thus facilitating debonding of the two components. After the wired is pulled through, the two components can be separated by manual twisting.

### Example 8

Solution 1 was prepared by mixing 514.8 parts CN9018, 275.79 parts CD611, 220.63 parts SR506A, 165.47 parts Bisomer PPA6, 110.31 parts soybean oil and 13 parts TPO-L to give a viscosity of 1300 cps. Solution 2 was prepared by adding 1 part HDDA to 9 parts of Solution 1.

Solutions 1 and Solution 2 were coated side-by-side on a glass slide and then laminated with 6 mil polyester terephthalate film (PET) to give a thickness of about 300 microns. These coatings were cured by passing 6 times under a Fusion H bulb to give a total energy of 3000 mJ/cm². The PET film and glass slide were then separated, leaving the cured coatings on the PET film.

A test for relative tack was done by applying tissue paper to UV cured coatings. After removing the tissue paper, relative tack was judged by the number of tissue fibers remaining on the coatings after removing the tissue paper. No tissue threads were observed on the coating made from Solution 2 containing HDDA. However, many threads and whole parts of tissue paper were observed on the coating made from Solution 1. The cured coating from Solution 2 containing HDDA was non-tacky to finger touch. However the cured coating from Solution 1 was very tacky to finger touch.

### Example 9

Solution 3 was prepared by adding 9 parts HDDA and 1 part TPO-L. Solution 3 was applied to one half of a glass side. Solution 1 was applied to the other side of the slide. The slide was tilted so that some of Solution 1 flowed partially over the coating from Solution 3. Solution 1 and Solution 3 were allowed to mix in the mutually contacted areas. A PET film was then placed over the coatings. The construction was UV cured in the same manner as Example 8. After curing in the same manner as Example 8, the PET film and glass slide were then separated, leaving the cured coatings on the PET film.

A test for relative tack was done in the same manner as Example 8. Tissue paper was applied to UV cured coatings. After removing the tissue paper, a few tissue threads were observed on the cured coating where Solution 1 and Solution 3 had mixed. However, many threads and whole parts of tissue paper were observed on the coating made from Solution 1. The cured coating where Solution 1 and Solution 3 had mixed had low tack to finger touch. However the cured coating from Solution 1 was very tacky to finger touch.

Examples 8 and 9 show that a multifunctional acrylate can be used to enhance edge cure to give a low-tack or non-tacky edge. The presence of the TPO ensures that all the HDDA will cure, even if it all doesn't get dissolved in the acrylate LOCA.

When 10 wt % HDDA is added to Solution 1, it cures to a non-tacky coating, indicating a multifunctional acrylate will crosslink the components of Solution 1, reducing tack. Solution 1 by itself cures to a very tacky coating.

When HDDA/TPO is painted on a glass surface and Solution 1 is allowed to flow into the painted area, the area of the mutually mixed components UV cures to a low-tack coating as demonstrated by relatively few paper threads being pulled out of a paper towel pressed against the coatings relative to Solution 1 by itself.

### Example 10

The following example illustrates preparation of an display panel assembly that may be made using two glass slides, a polarizer film, and first and second compositions. A sheet of polarizing film (Nitto Denko, Japan) may be laminated to a 2″×3″ glass slide (VWR, West Chester, Pa.). This laminated glass slide may become ultimately the bottom of a fully cured assembly.

Next, a first composition comprising an acrylate gel formulation may be prepared by mixing 95 g 2-ethylhexyl acrylate, 5 g acrylic acid, and 0.1 g IRGACURE 651 (photoinitiator from Ciba, Inc.), and then dispensed in a dogbone form on a major surface of the polarizing film as shown in FIG. 2. A second composition comprising an edge hardener may be prepared by mixing 90 g 2-ethylhexyl acrylate, 5 g acrylic acid, 5 g 1,6-hexanediol diacrylate, and 0.1 g IRGACURE 651, and dotted along the perimeter of the surface as shown in FIG. 2, and then spread with a cotton applicator tip to form a narrow band around the perimeter of the surface as shown in FIG. 2.

The other glass slide may then be placed onto the first and/or second compositions so that they spread evenly between the surfaces. The resulting assembly may then be exposed to UV light to effect reaction between the first and second compositions, bonding the substrates together with a gel surrounded by a non-tacky material.

### Thixotropic LOCAs

Compositions for Comparative Example 3 (C3) and Example 10-1 were prepared according to Table 5. Components were added to a white mixing container, a Max 300 (about 500 cm³), from FlackTek Inc., Landrum, S.C.), and mixed using a Hauschild Speedmixer™ DAC 600 FV, from FlackTek Inc., operating at 2200 rpm for 4 minutes. In the case of Example 10-1, the sides of the container were scraped down to make sure all the fumed silica was incorporated, then the container was mixed for an additional 4 minutes.

TABLE 5

| | C3 | | Ex10-1 | |
|---|---|---|---|---|
| Component | % Loading | Mass (g) | % Loading | Mass (g) |
| U-Pica 8967 | 68.4 | 69.8 | 50.0 | 150.00 |
| CD611 | | | 14.0 | 41.88 |
| KE311 | 7.1 | 7.2 | | |
| SR506A | 11.6 | 11.8 | 11.2 | 33.50 |
| Bisomer PPA6 | | | 8.4 | 25.13 |
| Soybean oil | | | 8.4 | 25.50 |
| 4-HBA | 9.8 | 10 | | |
| SILQUEST A-174 | 0.2 | 0.2 | | |
| Lucirin TPO-L | 2.9 | 3.00 | 1.0 | 3.00 |
| HDK H2ORH | | | 7 | 21.00 |

The mixture for Example 10-1 was sandwiched between 2″×3″ microscope slides at a thickness of about 200 microns. % T and haze were measured using a HazeGard Plus (BYK-Gardner USA, Columbia, Md.). The fresh coating had 92.9% T (uncorrected for glass) and a haze of 1.49%. After 72 hours at 60° C./85% RH, the coating had 93.0% T (uncorrected for glass) and a haze of 0.91%.

The viscosities for Comparative Example 3 and Example 10-1 were measured on an AR2000 Rheometer (TA Instruments, New Castle, Del.), equipped with a 40 mm, 1° stainless steel cone and plate from TA Instruments, New Castle, Del. at 25° C. The shear rate was increased from 0.001 sec⁻¹ to 100 sec⁻¹. Viscosities at various shear rates are shown in Table 6. When a bead of Example 10-1 was deposited on a glass slide from a syringe/needle assembly, it showed no perceivable sag (non-sag) to the naked eye after 1 minute. Example 10-1 meets the criteria specified herein for viscosity of 18,000 cps to 140,000 cps at a shear rate of 1 sec⁻¹ and a viscosity of 700,000 cps to 4,200,000 cps at 0.01 sec⁻¹. However a bead of C3 had significant sag to the naked eye after 1 minute despite a viscosity of 19,000 cps at 1 sec⁻¹. C3 meets the criterion herein for a viscosity of 18,000 cps to 140,000 cps at a shear rate of 1 sec⁻¹. However C3 has a viscosity of only 20,400 cps at a shear rate of 0.01 sec-1 and misses the criterion specified herein for a viscosity of 700,000 cps to 4,200,000 cps at 0.01 sec⁻¹.

TABLE 6

| | C3 | Ex10-1 |
|---|---|---|
| | Viscosity | Viscosity |
| Shear rate (sec⁻¹) | (cps) | (cps) |
| 0.01 | 20,400 | 4,159,000 |
| 0.1 | 19,000 | 870,600 |
| 1 | 19,000 | 132,800 |
| 10 | 19,100 | 30,000 |

The displacement creep values for Comparative Example 3 and Example 10-1 were measured using an AR2000 Rheometer and a 40 mm diameter, 1° cone at 25° C., and is defined as the rotational angle of the cone when a stress of 10 Pa is applied to the adhesive for two minutes. Example 10-1 has a displacement creep of 0.021 radians after two minutes and meets the criterion specified herein of <0.1 radians. However C3 fails this criterion with a displacement creep of 1.08 radians after two minutes.

Thixotropic liquid optically clear adhesives were prepared by adding the components in Table 7 to white mixing containers, a Max 300 (about 500 cm³), from FlackTek Inc., Landrum, S.C., and mixed using a Hauschild Speedmixer™ DAC 600 FV, from FlackTek Inc., operating at 2200 rpm. After mixing for 4 minutes, the sides of the containers were scraped down to make sure all the fumed silica was incorporated, then the containers were mixed for an additional 4 minutes.

TABLE 7

| | C4 | Ex11 | Ex12 |
|---|---|---|---|
| Component | % Loading | % Loading | % Loading |
| U-Pica 8967A | 11.2 | 34.2 | 15.8 |
| U-Pica 8966A | 7.6 | | 12.1 |
| Joncryl 960 | | | 26.2 |
| Joncryl 963 | 20 | | |
| KE311 | 26.9 | 11.4 | 18.9 |
| CD611 | | 12.3 | |
| SR335 | 11.0 | | |
| SR506A | 16.4 | 17.1 | 18.9 |
| Bisomer PPA6 | | 9.5 | |
| Soybean oil | | 9.5 | |
| A187 | | | 0.2 |
| A174 | 0.2 | | |
| TPO-L | | 1 | |
| Darocur 4265 | 2 | | 2 |
| Aerosil A200 | 4.8 | 5 | |
| Aerosil R805 | | | 5.9 |

The viscosities of Comparative Example 4 and Examples 11 and 12 were measured as described above for Comparative Example 3 and Example 10-1; results are shown in Table 8. The thixotropy was considered good if it had a viscosity of 18 Pa·s to 140 Pa·s at a shear rate of 1 sec⁻¹ and a viscosity of 700 Pa·s to 4200 Pa·s. at 0.01 sec⁻¹.

Comparative Example 4 and Examples 11 and 12 were each sandwiched between 2″×3″ microscope slides at a thickness of about 200 microns and cured using a 300 W/inch Fusion H bulb and a UVA energy of 3000 mJ/cm² as measured by a UV Power Puck (EIT, Inc., Sterling, Va.). Haze was measured using a HazeGard Plus (BYK-Gardner USA, Columbia, Md.). The values for haze are reported in Table 8. The cured adhesive was considered good if the haze was <1%.

Weight loss was measured by placing approximately 15 g of the thixotrope in a container, a Max 300 (about 500 cm³), from FlackTek Inc., Landrum, S.C., and subjecting the container with the thixotrope to a vacuum of 2000 Pa for 2 minutes at 25° C. The weight of the thixotrope before and after the vacuum treatment was used to calculate % weight loss, which is reported in Table 8. Example 11 with a weight loss of 0.033% gave no bubbling during vacuum lamination at a pressure of 2000 Pa whereas C4 with a weight loss of 0.177% gave considerable bubbling during vacuum lamination at a pressure of 2000 Pa.

TABLE 8

| | C4 | Ex11 | Ex12 |
|---|---|---|---|
| Viscosity (cps) | 4,182,000 | 1,480,000 | 974,000 |
| Shear rate 0.01 sec⁻¹ | | | |
| Viscosity (cps) | 686,000 | 613,000 | 185,000 |
| Shear rate 0.1 sec⁻¹ | | | |
| Viscosity (cps) | 123,000 | 91,000 | 55,600 |
| Shear rate 1 sec⁻¹ | | | |
| Thixotropy result | good | good | good |
| Haze | 5% | 0.4% | 0.7% |
| Haze result | poor | good | good |
| Weight Loss | 0.117% | 0.033% | |
| Bubbling during | yes | no | |
| vacuum lamination? | | | |

A number of embodiments of the invention have been described. It is understood that various modifications may be made without departing from the spirit and scope of the invention. Accordingly, other embodiments are within the scope of the following claims.

What is claimed is:

1. A display panel assembly comprising:
a display panel;
a substantially transparent substrate; and
a curable layer disposed between the display panel and the substantially transparent optical substrate, the curable layer comprising a first composition and a second composition, wherein the second composition by itself is not curable and only becomes curable when mixed with the first composition.

2. The display panel assembly of claim 1, wherein the first curable composition comprises a first ethylenically unsaturated compound having at least one ethylenically unsaturated group, and the second curable composition comprises a second ethylenically unsaturated compound having at least two ethylenically unsaturated groups, and the first and/or second compositions further comprise a catalyst.

3. The display panel assembly of claim 2, wherein the first curable composition further comprises the second ethylenically unsaturated compound, wherein the concentration of the second ethylenically unsaturated compound in the second curable composition is greater than the concentration of the second ethylenically unsaturated compound in the first curable composition.

4. The display panel assembly of claim 2, wherein the first curable composition further comprises a third ethylenically unsaturated compound having at least two ethylenically unsaturated groups, and the third ethylenically unsaturated compound is different from the second ethylenically unsaturated compound.

5. The display panel assembly of claim 4, wherein the second ethylenically unsaturated compound has more ethylenically unsaturated groups per molecule than the third ethylenically unsaturated compound.

6. The display panel assembly of claim 4, wherein the concentration of ethylenically unsaturated groups in the second curable composition is greater than that of the first curable composition.

7. The display panel assembly of claim 2, wherein the catalyst comprises a photoinitiator

8. The display panel assembly of claim 1, wherein the second composition cures faster than the first composition.

9. The display panel assembly of claim 1, wherein the display panel and the substantially transparent optical substrate include a gap therebetween and wherein the curable layer substantially fills the gap between the display panel and the substantially transparent optical substrate.

10. The display panel of claim 1, wherein the curable layer covers a major portion of at least one of the display panel and the substantially transparent substrate.

11. The display panel of claim 1, wherein the display panel comprises one of a liquid crystal display, plasma display panel, organic electroluminescence panel and an electrophoretic display.

12. A display panel assembly of claim 11, wherein the display panel is an organic electroluminescence panel and wherein the organic electroluminescence panel comprises one of an organic light emitting diode or a polymer light emitting diode.

13. The display panel assembly of claim 1, wherein the curable layer, after being cured, has a haze value of less than 1.
